(19) United States
(12) Patent Application Publication
(10) Pub. No.: US 2024/0136446 A1
(43) Pub. Date: Apr. 25, 2024

(54) METHOD FOR MANUFACTURING AN ELECTRONIC POWER DEVICE, AND DEVICE OBTAINED BY THIS METHOD

(71) Applicant: Commissariat á I'Énergie Atomique et aux Énergies Alternatives, Paris (FR)

(72) Inventor: Florian Dupont, Grenoble Cedex 9 (FR)

(73) Assignee: Commissariat á I'Énergie Atomique et aux Énergies Alternatives, Paris (FR)

(21) Appl. No.: 18/493,562

(22) Filed: Oct. 23, 2023

(30) Foreign Application Priority Data
Oct. 24, 2022 (FR) 2211044

(51) Int. Cl. H01L 29/861; H01L 21/02; H01L 29/78

(52) U.S. Cl. CPC H01L 29/8613; H01L 21/02381; H01L 21/0254; H01L 29/7827

(57) ABSTRACT

A method for manufacturing a power electronic device including the following successive steps: a) providing a silicon semiconductor substrate, the substrate having a front face and a rear face, opposite the front face; b) forming, by epitaxial growth from the front face of the substrate, a first continuous layer of at least one nitrided transition metal coating the front face of the substrate; and c) forming, on the first layer, by epitaxial growth from the front face of the substrate, at least one second layer of a III-V material, preferably III-N.

### CROSS REFERENCE TO RELATED APPLICATIONS

This application claims priority to French application number 2211044, filed Oct. 25, 2022, the contents of which is incorporated by reference in its entirety.

### TECHNICAL FIELD

The present description relates generally to electronic devices. The present description relates more particularly to a method for manufacturing a power electronic device based on gallium nitride (GaN), and to a device obtained by this method.

### BACKGROUND ART

Power electronic devices based on gallium nitride have been proposed. However, these devices and their manufacturing methods suffer from various drawbacks.

### SUMMARY OF INVENTION

One object of one embodiment is to overcome some or all of the drawbacks of known power electronic devices based on gallium nitride.

To this end, one embodiment provides a method for manufacturing a power electronic device comprising the following successive steps:
a) providing a silicon semiconductor substrate, the substrate having a front face and a rear face opposite the front face;
b) forming, by epitaxially growing, from the front face of the substrate, a first continuous layer of at least one nitrided transition metal coating the front face of the substrate; and
c) forming, by epitaxially growing, on the first layer on the front face side of the substrate, at least one second layer of a III-V material, preferably III-N.

According to one embodiment, the first continuous layer is made of a nitrided transition metal or an alloy of nitrided transition metals selected from titanium nitride, vanadium nitride, chromium nitride, zirconium nitride, niobium nitride, molybdenum nitride, hafnium nitride, and tantalum nitride.

According to one embodiment, the method further comprises, between steps b) and c), a step of forming, by pulsed laser ablation from a face of the first layer opposite the front face of the substrate, an epitaxial third layer of a material selected from aluminum nitride, gallium nitride, indium nitride, and alloys of these materials, the third layer coating said face of the first layer.

According to one embodiment, the method further comprises, between steps b) and c), a step for etching the first layer and the substrate.

According to one embodiment, the method further comprises, between steps a) and b), a step for etching the substrate.

According to one embodiment, the method further comprises, after step c), a step for forming a first conduction electrode of the device, coating a face of said at least one second layer opposite the front face of the substrate, and a second conduction electrode of the device, coating the rear face of the substrate.

According to one embodiment, the semiconductor substrate is substantially monocrystalline, with the front face of the substrate having a (111) crystalline orientation.

According to one embodiment, in step b), the first continuous layer is formed by pulsed laser ablation.

According to one embodiment, the method further comprises, between steps b) and c), a step for forming a selective growth mask.

One embodiment provides a power electronic device comprising:
a silicon semiconductor substrate, the substrate having a front face and a rear face opposite the front face;
a first continuous epitaxial layer of at least one nitrided transition metal coating the front face of the substrate; and
at least one second continuous epitaxial layer of a III-V material, preferably III-N, located on the first layer.

According to one embodiment, the device further comprises a first conduction electrode, coating a face of said at least one second layer opposite the front face of the substrate, and a second conduction electrode, coating the rear face of the substrate.

According to one embodiment, the first and second electrodes are anode and cathode electrodes respectively, the device being of the diode type.

According to one embodiment, the substrate comprises a first part, located in regard of the anode electrode, having a thickness greater than that of a second ring-shaped part of the substrate surrounding the first part.

According to one embodiment, the device further comprises a third continuous layer of a material selected from aluminum nitride, gallium nitride, and indium nitride, the third layer coating said face of the first layer.

According to one embodiment, the device further comprises a control electrode penetrating into said at least one second layer, the device being of the transistor type.

According to one embodiment, the flanks of said at least one second layer are coated with a passivation layer.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 is a cross-sectional view schematically and partially illustrating an example of a power electronic device according to one embodiment;

FIG. 2A, FIG. 2B, and FIG. 2C are cross-sectional views schematically and partially illustrating successive steps of an example method for manufacturing the device shown in FIG. 1;

FIG. 3 is a sectional view schematically and partially illustrating an example of a power electronic device according to one embodiment;

FIG. 4 is a cross-sectional view schematically and partially illustrating an example power electronic device according to one embodiment; and

FIG. 5 is a cross-sectional view schematically and partially illustrating an example power electronic device according to one embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the complete realization of the power devices, including any control circuits, has not been described in detail, as the realization of such devices is within the scope of those skilled in the art from the teaching of the present description.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

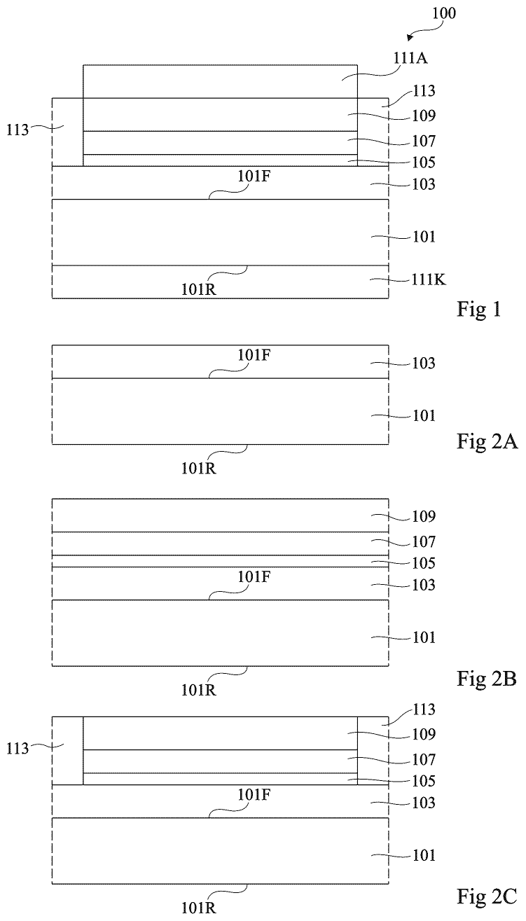

FIG. 1 is a sectional view schematically and partially illustrating an example power electronic device 100 according to one embodiment.

More specifically, the device 100 shown in FIG. 1 is of the diode type, for example a power diode suitable for use in applications implementing power levels typically ranging from a few milliwatts to several tens of watts, e.g. applications for converting electrical energy. The described embodiments are particularly advantageous for the realization of power electronic components with a high breakdown voltage, for example higher than 450 V.

The device 100 shown in FIG. 1 is, for example, an individually controllable discrete component having, when viewed from above, a surface area of, for example, between a few square micrometers and a few square millimeters.

In the illustrated example, the device 100 comprises a supporting substrate 101 made of a semiconductor material, such as silicon (Si). The supporting substrate 101 is, for example, a wafer or wafer piece made of substantially single-crystal silicon. The material of the substrate 101 is, for example, heavily doped with a first conductivity type, such as n-type (n+ doping). For example, the substrate 101 has a doping level comprised between 1×1017 at./cm3 and 5×1020 at./cm3.

In the represented example, a continuous layer 103 made of a nitrided transition metal coats a face 101F, called “front face”, of the substrate 101 (the top face of the substrate 101, according to the orientation of FIG. 1). In the case where the supporting substrate 101 is a single-crystal silicon wafer or wafer piece, the front face 101F corresponds, for example, to a (111) crystal plan of the crystal, the substrate then being oriented (111). In the illustrated example, the layer 103 extends laterally over, and in contact with, the front face 101F of the substrate 101. By way of example, the layer 103 has a thickness of between 0.5 nm and 100 nm, for example around 20 nm.

For example, the nitrided transition metal in layer 103 is selected from titanium nitride (TiN), vanadium nitride (VN), chromium nitride (CrN), zirconium nitride (ZrN), niobium nitride (NbN), molybdenum nitride (MoN), hafnium nitride (HfN), and tantalum nitride (TaN). The nitrided transition metal is, for example, a mononitride. However, the present description is not limited to this case, as the nitrided transition metal may alternatively have a different stoichiometry to that of a mononitride (e.g. Ta₂N, Ta₅N₆ or Ta₃N₅, for tantalum nitride). Furthermore, the crystal structure of the nitrided transition metal in layer 103 is, in the case of a polymorphic compound, selected from the different structures, or forms, known for this compound (e.g. α and ε forms, for tantalum mononitride) so as to facilitate crystal compatibility with the substrate material 101. Alternatively, the layer 103 is made of an alloy of at least two nitrided transition metals, for example a Ta_{0.5}Ti_{0.5}N alloy.

Furthermore, the continuous layer 103 may have a single-layer or multilayer structure. In the case of a multilayer structure, the layer 103 comprises, for example, a stack of at least two layers of different materials, each layer being made of a nitrided transition metal, or a nitrided transition metal alloy.

The nitrided transition metal in the layer 103 is, for example, an electrically conductive metal nitride. In this case, the layer 103 is electrically conductive.

According to one embodiment, the device 100 also comprises at least one continuous gallium nitride (GaN) layer located on the nitrided transition metal layer 103. In the example shown in FIG. 1, the device 100 more specifically comprises a continuous layer 105 of gallium nitride highly doped of the first conductivity type (n+ doping, in this example) coating part of the face of the nitrided transition metal layer 103 opposite the substrate 101 (the upper face of the layer 103, according to the orientation of FIG. 1). In this example, the layer 105 is coated, on its face opposite the substrate 101 (the upper face of layer 105, according to the orientation of FIG. 1), with another layer 107 made of gallium nitride lightly doped of the first conductivity type (n-doping, in this example) itself coated, on its side opposite the substrate 101 (the upper side of the layer 107, according to the orientation shown in FIG. 1), a further layer 109 of gallium nitride lightly doped of a second conductivity type (p-doping, in this example), opposite the first conductivity type.

As an example, the layer 105 has a doping level of between 1×10¹⁷ at./cm³ and 5×10²⁰ at./cm³, and layers 107, and 109 have each a lower doping level than the layer 105, for example between 1×10¹⁰ at./cm³ and 1×10¹⁷ at./cm³. The doping levels of layers 107, and 109 are, for example, substantially equal.

According to one embodiment, the nitrided transition metal layer and the one or more gallium nitride layers on the front face of the substrate are epitaxial layers, i.e. formed by epitaxial growth, or epitaxy. In the illustrated example, the layers 103, 105, 107, and 109 result from the implementation of successive epitaxial steps from the front face 101F of the substrate 101. In other words, the deposited layers exhibit lateral continuity (i.e. in the horizontal plane, according to the orientation of FIG. 1) of the crystal structure, or vertical crystal alignment between the different deposited layers. In this way, the substrate 101 and the layers 103, 105, 107, and 109 have crystal structures with common symmetry elements and similar lattice parameters. The crystal structure of each layer 103, 105, 107, 109 is organized with respect to the crystal structure, and in particular with respect to the crystal plane of the upper surface, of the underlying substrate, in the case of the layer 103, or of the underlying layer 103, 105, 107, in the case of layers 105, 107, and 109, respectively.

The nitrided transition metal layer 103 enables lattice parameter matching between the substrate 101 and the layer 105.

In the illustrated example, the device 100 also includes electrodes arranged on either side of the structure formed by the substrate 101 and layers 103, 105, 107, and 109. More specifically, the device 100 comprises an anode electrode 111A coating the face of the gallium nitride layer 109 opposite the substrate 101 (the top face of layer 109, according to the orientation shown in FIG. 1) and a cathode electrode 111K coating a face 101R of the substrate 101 opposite its front face 101F. Face 101R, referred to as the “rear face” of the substrate 101, corresponds, according to the orientation of FIG. 1, to the bottom face of the substrate 101. By way of example, electrodes 111A and 111K are made of an electrically conductive material, such as a metal or metal alloy.

In the example represented in FIG. 1, the flanks of the gallium nitride layers 105, 107, and 109 are coated with a passivation layer 113. The passivation layer 113 protects the layers 105, 107, and 109 from oxidation. As an example, the passivation layer 113 is made of silicon nitride (SiNₓ), silicon dioxide, spin-on glass (SOG), or tantalum oxide (TaOₓ).

FIG. 2A, FIG. 2B, and FIG. 2C are cross-sectional views schematically and partially illustrating successive steps in an example method for manufacturing the device 100 of FIG. 1.

More precisely, FIG. 2A illustrates a structure obtained after a step in which the nitrided transition metal layer 103 is formed by heteroepitaxy from the front face 101F of the substrate 101.

Layer 103 is formed, for example, by PLD (Pulsed Laser Deposition), also known as pulsed laser ablation deposition. PLD deposition involves ablating the surface of a target of the material to be deposited by means of a pulsed laser, so as to transfer the material into a plasma, and then, via the plasma, onto the target substrate. As an example, during PLD deposition of the layer 103, the substrate 101 is heated to a temperature of between 400° C. and 1,000° C., e.g. around 700° C.

One advantage of PLD deposition is that it can deposit complex materials with good crystalline quality at relatively low temperatures, e.g. around 700° C., without damaging the target substrate. Another advantage of PLD deposition is that it can be used to epitaxialize the deposited materials.

Alternatively, the nitrided transition metal layer 103 is formed by another physical vapor deposition (PVD) method, such as evaporation or sputtering.

The step of forming the layer 103 can be followed by a step of deoxidizing the upper surface of this layer, for example with hydrofluoric acid (HF), so as to facilitate subsequent steps in the method.

More precisely, FIG. 2B illustrates a structure obtained after forming gallium nitride layers 105, 107, and 109 on a nitrided transition metal layer 103. Layers 105, 107, and 109 are successively epitaxialized from the top of the layer 103, for example by MOCVD (Metal-Organic Chemical Vapor Deposition). More specifically, gallium nitride layer 105 is heteroepitaxially formed from the top surface of the nitrided transition metal layer 103, and the gallium nitride layers 107 and 109 are then homoepitaxially formed from the top surfaces of the layers 105 and 107 respectively.

In practice, for example, the nitrided transition metal layer 103 is first formed under vacuum in a first reactor. The structure illustrated in FIG. 2A is then transferred to a second reactor, for example. Gallium nitride layers 105, 107, and 109 are then formed, under vacuum, in the second reactor. Alternatively, the layer 105 can be formed by PLD deposition in the first reactor, with layers 107, and 109 then formed by MOCVD in the second reactor. Optionally, a further gallium nitride or aluminum-gallium nitride layer can, in this variant, be deposited by MOCVD in the second reactor after PLD deposition of the layer 105 in the first reactor. This avoids exposing the layer 103 to air. It can also facilitate epitaxy rework during MOCVD deposition.

More precisely, FIG. 2C illustrates a structure obtained by structuring gallium nitride layers 105, 107, and 109, and depositing the passivation layer 113. Layers 105, 107, and 109 are structured, for example, by photolithography followed by etching.

The passivation layer 113 is then deposited on the structure on the front face 101F of substrate 101, for example, and then thinned, for example by Chemical-Mechanical Polishing (CMP), to expose the top surface of the gallium nitride layer 109. Once these steps have been completed, the passivation layer 113 coats the gallium nitride flanks of the layers 105, 107, and 109, and the nitrided transition metal top surface of the layer 103. In the illustrated example, the passivation layer 113 is flush with the top surface of the gallium nitride layer 109.

Based on the structure illustrated in FIG. 2C, the anode 111A and cathode 111K electrodes of the device 100 can then be formed on the top surface of the gallium nitride layer 109 and on the rear face 101R of the substrate 101, respectively.

Alternatively, the passivation layer 113 can be deposited and then thinned after the electrodes 111A and 111K of the device 100 have been formed.

An advantage of the method hereinabove described in relation to FIG. 1 is that it is less costly and simpler to implement than current methods for manufacturing gallium nitride-based power electronic devices, for example methods for forming a conduction electrode on a heavily doped GaN layer, the methods comprising steps for removing the supporting substrate, and transferring the stack comprising the GaN layers to another substrate, methods for forming one or more vias through the supporting substrate, and for conformally depositing an electrode in each of these vias, and methods for re-contacting from the rear face of the substrate in which a buffer layer, typically of aluminum nitride, is interposed between the front face of the supporting substrate and the stack comprising the GaN layers.

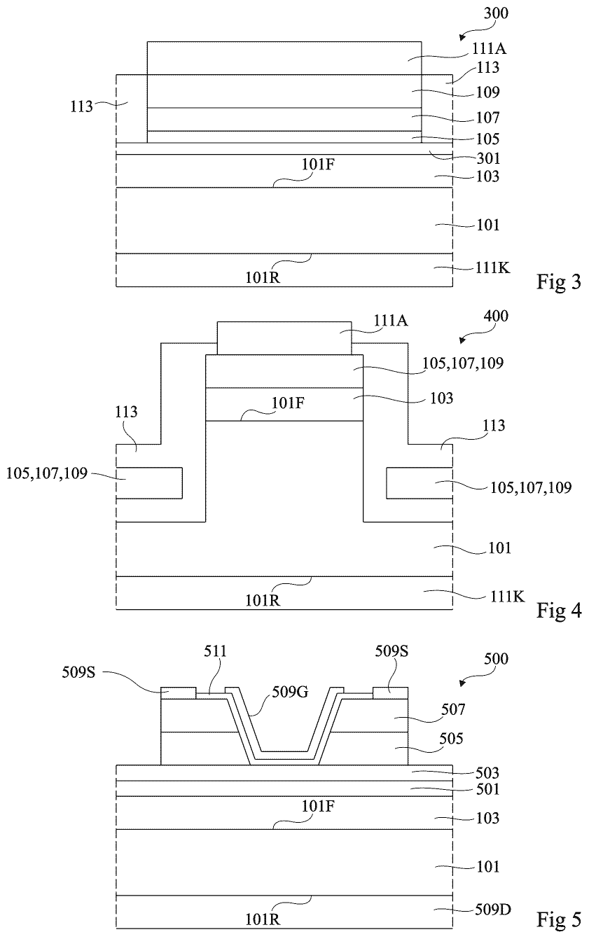

FIG. 3 is a cross-sectional view schematically and partially illustrating an example power electronic device 300 according to one embodiment. The device 300 illustrated in FIG. 3 comprises elements in common with the device 100 illustrated in FIG. 1, and these common elements will not be detailed again below.

The device 300 of FIG. 3 differs from the device 100 of FIG. 1 in that it comprises a layer 301 interposed between the nitrided transition metal layer 103 and the gallium nitride layer 105. The material of layer 301 is, for example, an inorganic semiconductor material, e.g. a III-V compound comprising at least a first Group III element, a second Group V element and, optionally, a third element, e.g. a Group III element other than the first element. Preferably, the Group V element is nitrogen (N), so that the material of layer 301 is a III-N compound. By way of example, the material of layer 301 is gallium nitride (GaN), aluminum nitride (AlN), boron nitride (BN), indium nitride (InN), or an alloy of one or more of these materials, for example aluminum gallium nitride (AlGaN). The thickness of the layer 301 is selected so as to allow current flow, by tunneling effect, between the gallium nitride layer 105 and the nitrided transition metal layer 103. By way of example, the layer 301 has a thickness of less than 5 nm, for example between 1 and 2 nm, or around 1 nm.

The material of the layer 301 of the device 300 can be heavily doped with the first conductivity type (n-type, in this example). If the layer 301 is made of gallium nitride, silicon (Si) can be used to achieve a high level of n-type doping (n++ doping). By way of example, the layer 301 has a doping level of between 1×10¹⁷ at./cm³ and 5×10²¹ at./cm³, for example equal to around 1×10²⁰ at./cm³.

By way of example, the layer 301 is formed, for example by PLD, between the steps previously described in relation to FIGS. 2A and 2B. If the layer 301 is made of gallium nitride heavily n-doped with silicon atoms, a GaN:Si target can be used during PLD deposition.

In the illustrated example, the layer 301 is left untouched after the step for structuring the gallium nitride layers 105, 107, and 109 previously described in relation to FIG. 2C. Alternatively, the layer 301 could be structured in a similar way to layers 105, 107, and 109 in the step illustrated in FIG. 2C.

An advantage of the device 300 is that layer 301 can provide polarity control of the nitrided transition metal layer 103. Layer 301 also protects layer 103 against oxidation.

FIG. 4 is a cross-sectional view schematically and partially illustrating an example of a power electronic device 400 according to one embodiment. The device 400 illustrated in FIG. 4 comprises elements in common with the device 100 illustrated in FIG. 1, which will not be detailed again below.

The device 400 of FIG. 4 differs from the device 100 of FIG. 1 in that the substrate 101 comprises a first part, located in regard of the anode electrode 111A, having a thickness (distance between the front 101F and rear 101R faces of the substrate 101) greater than that of a second part of the substrate 101 of annular shape surrounding the first part.

The differences in thickness between the first and second parts of the substrate 101 are obtained, for example, by structuring the substrate 101 prior to depositing the gallium nitride layers 105, 107, and 109. In order not to overload the drawing, the layers 105, 107, and 109 have been symbolized by a single layer in FIG. 4.

In the illustrated example, the nitrided transition metal layer 103 coats only the front face 101F of the first part of the substrate 101. By way of example, the layer 103 is first formed over the entire front face 101F of substrate 101, then the substrate 101 and layer 103 are patterned, for example by photolithography followed by etching, prior to depositing the gallium nitride layers 105, 107, and 109. Alternatively, the nitrided transition metal layer 103 can be deposited on the entire front face 101F of the substrate 101 after the substrate 101 has been patterned.

In the illustrated example, the stack formed by gallium nitride layers 105, 107, and 109 is discontinuous, with a first part located in regard of the anode electrode 111A and a second ring-shaped part surrounding the first part. In a case where the substrate 101 and the stack formed by layers 105, 107, and 109 have a large difference in thermal expansion coefficient, for example when the substrate 101 is made of silicon, this advantageously makes it possible to avoid or limit the appearance of defects, such as discontinuities or cracks, in gallium nitride layers 105, 107, and 109.

According to another example, the layer 103 is first deposited by pulsed laser ablation on the top surface 101F of the silicon substrate 101. In this example, the substrate 101 has for example a substantially flat top surface 101F, and the layer 103 is continuous. A layer of, for example, silicon nitride (Si₃N₄), silicon dioxide, or alumina is then deposited on and in contact with the top face of layer 103 and structured, for example by photolithography followed by etching, to form a growth mask comprising through apertures at the bottom of which are exposed parts of the top face of the underlying layer 103. Selective MOCVD growth is then carried out so that gallium nitride pads are formed, for example pads each comprising a stack of gallium nitride layers analogous to layers 105, 107, and 109, within the openings of the growth mask. Alternatively, a stack comprising the layers 103 and 105 can be deposited by PLD before the growth mask is formed. Again, this allows the occurrence of cracks in the gallium nitride layers to be avoided or limited.

FIG. 5 is a sectional view schematically and partially illustrating an example power electronic device 500 according to one embodiment.

The device 500 illustrated in FIG. 5 is more precisely of the transistor type, for example a power transistor designed to allow or prevent the passage of an electric current between its conduction terminals.

The device 500 illustrated in FIG. 5 comprises elements in common with the device 100 illustrated in FIG. 1. These common elements will not be detailed again below.

In particular, the device 500 includes the doped substrate 101 of the first conductivity type (n-type, in this example), the front face 101F of which is coated with the nitrided transition metal layer 103. The device 500 of FIG. 5 differs from the device 100 of FIG. 1 in that the device 500 comprises a vertical stack comprising, in order from the top face of layer 103, a first continuous layer 501 of GaN doped with the first conductivity type (the n-type, in this example), a second continuous layer 503 of unintentionally doped GaN, a third continuous layer 505 of doped GaN of the second conductivity type (p-type, in this example) and a fourth continuous layer 507 of doped GaN of the first conductivity type (n-type, in this example).

In the illustrated example, the layer 501 coats the top face of the layer 103, and the layer 503 coats the top face of the layer 501. Furthermore, the layer 505 coats part of the top face of the layer 503, and the layer 507 coats the top face of the layer 505.

The device 500 further comprises a gate electrode 509G, extending vertically through the thickness of the layers 505 and 507 from the top face of layer 507, source electrodes 509S, located on and in contact with the top face of the layer 507 on either side of the gate electrode 509G, and a drain electrode 509D coating the rear face 101R of the substrate 101.

In the illustrated example, device 500 also includes an electrically insulating layer 511, for example made of alumina (Al2O3), interposed between the gate electrode 509G, on the one hand, and the GaN layers 505 and 507, on the other. The layer 511 isolates the electrode 509G from layers 505 and 507. In the example illustrated in FIG. 5, the gate electrode 509G and layer 511 form a gate region passing through layers 505 and 507, and interrupting at the top of the layer 503. However, this example is not limitative, as the gate region formed by the electrode 509G and layer 511 can penetrate the stack formed by layers 501, 503, 505, and 507 to a depth different from that shown in FIG. 5.

In the illustrated example, the insulating layer 511 extends laterally, below the electrode 509G and over and in contact with the top face of the layer 507, to the flanks of source electrodes 509S.

Although not illustrated in FIG. 5, a passivation layer, for example a layer analogous to the layer 113 in FIGS. 1, 3, and 4, can coat the flanks of gallium nitride layers 505 and 507 of the device 500.

The power devices 100, 300, 400, and 500 illustrated in FIGS. 1, 3, 4 and 5 each have a so-called “vertical” architecture, in which the conduction electrodes (anode 111A and cathode 111K, for the devices 100, 300, and 400, and source 509S and drain 509D, for the device 500) are located on either side of the stack comprising the substrate 101 and gallium nitride layers. This advantageously makes it possible to obtain higher breakdown voltages, particularly compared with power devices featuring a so-called “lateral” structure, in which the conduction electrodes are located on the same side of the substrate.

Various embodiments and variants have been described. Those skilled in the art will understand that certain features of these embodiments can be combined and other variants will readily occur to those skilled in the art. In particular, although diode and transistor structures and manufacturing methods have been detailed above in relation to FIGS. 1 to 5, the embodiments described apply to other types of power components featuring vertical architecture.

Although layers 105, 107, 109, 501, 503, 505, and 507 are made of gallium nitride in the hereinabove detailed embodiments, those skilled in the art are more generally able to foresee these layers being made of any III-V material, preferably a III-N material.

Furthermore, those skilled in the art will be able to adapt the method for manufacturing the device 100 described in relation to FIGS. 2A to 2C to produce the devices 300, 400, and 500.

Finally, the practical implementation of the embodiments and variants described herein is within the capabilities of those skilled in the art based on the functional description provided hereinabove. In particular, although embodiments have been described above in which the first conductivity type is n and the second conductivity type is p, those skilled in the art is able to transpose the embodiments of the present description to the case where the conductivity types are reversed.

1. A method for manufacturing a power electronic device comprising the following successive steps:
a) providing a silicon semiconductor substrate, the substrate having a front face and a rear face, opposite the front face;
b) forming, by epitaxial growth from the front face of the substrate, a first continuous layer of at least one nitrided transition metal coating the front face of the substrate; and
c) forming, on the first layer, by epitaxial growth from the front face side of the substrate, at least one second layer of a III-V material, preferably III-N,
wherein the first layer is of titanium nitride and extends laterally over and in contact with the front face of the substrate.

2. The method according to claim 1, further comprising, between steps b) and c), a step of forming, by pulsed laser ablation from a face of the first layer opposite the front face of the substrate, an epitaxial third layer of a material selected from aluminum nitride, gallium nitride, indium nitride, and alloys of these materials, the third layer coating said face of the first layer.

3. The method according to claim 1, further comprising, between steps b) and c), a step of etching the first layer and the substrate.

4. The method according to claim 1, further comprising, between steps a) and b), a step of etching the substrate.

5. The method according to claim 1, further comprising, after step c), a step of forming a first conduction electrode of the device, coating a face of said at least one second layer opposite the front face) of the substrate, and a second conduction electrode of the device, coating the rear face of the substrate.

6. The method according to claim 1, wherein the semiconductor substrate is substantially monocrystalline, the front face of the substrate having a crystalline orientation.

7. The method according to claim 1, wherein, in step b), the first continuous layer is formed by pulsed laser ablation.

8. The method according to claim 1, further comprising, between steps b) and c), a step of forming a selective growth mask.

9. A power electronic device comprising:
a silicon semiconductor substrate, the substrate having a front face and a rear face, opposite the front face;
a first continuous epitaxial layer of at least one nitrided transition metal coating the front face of the substrate; and
at least one second continuous epitaxial layer of a III-V material, preferably III-N, located on the first layer,
wherein the first layer is of titanium nitride and extends laterally over and in contact with the front face of the substrate.

10. The device according to claim 9, further comprising a first conduction electrode, coating a face of said at least one second layer opposite the front face of the substrate, and a second conduction electrode, coating the rear face of the substrate.

11. The device according to claim 10, wherein the first and second electrodes are anode and cathode electrodes respectively, the device being of the diode type.

12. The device according to claim 11, wherein the substrate comprises a first part, located in regard of the anode electrode, having a thickness greater than that of a second part of the substrate of annular shape surrounding the first part.

13. The device according to claim 9, further comprising a third continuous layer of a material selected from aluminum nitride, gallium nitride, and indium nitride, the third layer coating said face of the first layer.

14. The device according to claim 10, further comprising a control electrode penetrating inside said at least one second layer, the device being of the transistor type.

15. The device according to claim 9, wherein the flanks of said at least one second layer are coated with a passivation layer.
